(19) United States
(12) Patent Application Publication
(10) Pub. No.: US 2004/0262705 A1
(43) Pub. Date: Dec. 30, 2004

(54) Solid-state image sensor and method of manufacturing solid-state image sensor

(75) Inventors: Makoto Izumi, Motosu-gun (JP); Kazuhiro Sasada, Hashima-shi (JP); Mitsuru Okigawa, Nagoya-shi (JP)

Correspondence Address: McDERMOTT, WILL & EMERY, 600 13th Street, N.W., Washington, DC, 20005-3096, US

(73) Assignee: SANYO ELECTRIC CO., LTD.

(21) Appl. No.: 10/874,325

(22) Filed: Jun. 24, 2004

(30) Foreign Application Priority Data
Jun. 25, 2003 (JP) JP2003-180407

(51) Int. Cl. H01L 27/00; H01L 31/0232

(52) U.S. Cl. 257/432

(57) ABSTRACT

A solid-state image sensor having high condensability is provided. This solid-state image sensor comprises a plurality of photodetection parts formed on a substrate and a plurality of lenses consisting of an inorganic insulator for condensing light on the photodetection parts, while each adjacent pair of lenses are so connected with each other as to include no substantially flat region on the boundary therebetween and the boundary between each adjacent pair of lenses has a prescribed thickness.

### BACKGROUND OF THE INVENTION

1. Field of the Invention

The present invention relates to a solid-state image sensor and a method of manufacturing a solid-state image sensor, and more particularly, it relates to a solid-state image sensor comprising a lens for condensing incident light on a photodetection part having a photoelectric conversion function and a method of manufacturing such a solid-state image sensor.

2. Description of the Background Art

A solid-state image sensor comprising microlenses for condensing incident light on photodetection parts having a photoelectric conversion function is known in general, as disclosed in Japanese Patent Laying-Open No. 2000-68491, for example.

FIG. 22 is a sectional view showing the structure of an exemplary conventional solid-state image sensor. Referring to FIG. 22, a plurality of pixel separation parts 121 for separating pixels from each other are formed on a prescribed region of the surface of an Si substrate 120 in the exemplary conventional solid-state image sensor. Further, photodetection parts 122 having a photoelectric conversion function of converting light received therein to signal charges are formed between the pixel separation parts 121 of the Si substrate 120. An interlayer dielectric film 123 is formed on the Si substrate 120 provided with the pixel separation parts 121 and the photodetection parts 122. Screen films 124 having a function of preventing light from entering prescribed regions of the interlayer dielectric film 123 are formed on the prescribed regions. Another interlayer dielectric film 125 is formed to cover the screen films 123 and the interlayer dielectric film 123. A plurality of microlenses 126 for condensing light on the photodetection parts 122 are formed on the interlayer dielectric film 125 in correspondence to the plurality of photodetection parts 122 respectively. Boundaries 126a between the adjacent ones of the microlenses 126 are formed with substantially flat regions. The microlenses 126 inwardly refract light incident upon the same on the surfaces thereof thereby condensing the light on the photodetection parts 122.

In the exemplary conventional solid-state image sensor shown in FIG. 22, however, light components incident upon the boundaries 126a between the adjacent microlenses 126 are not inwardly refracted due to the substantially flat regions. In other words, the flat boundaries 126a between the adjacent microlenses 126 have no function of condensing light on the photodetection parts 122, disadvantageously resulting in incident light partially uncondensable onto the photodetection parts 122 on the boundaries 126a between the adjacent microlenses 126. Therefore, it is difficult to improve condensation efficiency for the photodetection parts 122. Consequently, it is disadvantageously difficult for the solid-state image sensor to attain high condensability.

The solid-state image sensor disclosed in the aforementioned Japanese Patent Laying-Open No. 2000-68491 also has substantially flat regions on the boundaries between adjacent microlenses, and hence it is disadvantageously difficult for the solid-state image sensor to attain high condensability, similarly to the exemplary conventional solid-state image sensor shown in FIG. 22.

### SUMMARY OF THE INVENTION

The present invention has been proposed in order to solve the aforementioned problem, and an object of the present invention is to provide a solid-state image sensor having high condensability.

Another object of the present invention is to provide a method of manufacturing a solid-state image sensor capable of easily manufacturing a solid-state image sensor having high condensability.

In order to attain the aforementioned objects, a solid-state image sensor according to a first aspect of the present invention comprises a plurality of photodetection parts formed on a substrate and a plurality of lenses consisting of an inorganic insulator for condensing light on the photodetection parts. Each adjacent pair of lenses are so connected with each other as to include no substantially flat region on the boundary therebetween, and the boundary between each adjacent pair of lenses has a prescribed thickness. Throughout the specification, the term “inorganic insulator” is directed to a wide concept including SiN or the like.

In the solid-state image sensor according to the first aspect, as hereinabove described, each adjacent pair of lenses are so connected with each other as to include no substantially flat region on the boundary therebetween so that no part of incident light is uncondensable on the boundary between the adjacent pair of lenses dissimilarly to lenses including a substantially flat region having no function of condensing light on photodetection parts on the boundary therebetween. Thus, condensation efficiency for the photodetection parts can be improved as compared with the lenses including a substantially flat region having no function of condensing light on the photodetection parts on the boundary therebetween, whereby the solid-state image sensor can attain high condensability. Further, the lenses made of an inorganic insulator generally having a refractive index of at least about 1.6 can be provided with a large refractive index as compared with lenses made of a resin layer having a refractive index of about 1.5. Thus, condensation efficiency through the lenses can be improved. Further, the boundary between the adjacent pair of lenses is formed to have the prescribed thickness so that moisture can be inhibited from penetrating into the solid-state image sensor through the boundary between the adjacent pair of lenses as compared with lenses adjacent to each other through a boundary having a thickness of substantially zero. Thus, moisture resistance of the solid-state image sensor can be improved. Further, the boundary between the adjacent pair of lenses is so formed as to have the prescribed thickness that no passivation film may be separately provided on the lenses for preventing penetration of moisture, whereby the thickness of the solid-state image sensor can be inhibited from increase.

In the aforementioned solid-state image sensor according to the first aspect, the boundary between each adjacent pair of lenses preferably has a thickness of at least about 10 nm. According to this structure, moisture can be efficiently inhibited from penetrating into the solid-state image sensor through the boundary between the adjacent pair of lenses. Thus, the moisture resistance of the solid-state image sensor can be improved. Further, the boundary between the adjacent pair of lenses is so formed as to have the thickness of at least about 10 nm that no passivation film may be separately provided on the lenses for preventing penetration of moisture, whereby the thickness of the solid-state image sensor can be inhibited from increase.

In the aforementioned solid-state image sensor according to the first aspect, the lenses consisting of an inorganic insulator preferably have a refractive index of at least about 1.6. According to this structure, the lenses can be easily provided with a large refractive index. Thus, the condensation efficiency through the lenses can be easily improved.

In the aforementioned solid-state image sensor according to the first aspect, the plurality of lenses are preferably formed by a single layer. According to this structure, no interfaces are formed dissimilarly to lenses formed by a plurality of layers. Thus, the solid-state image sensor can be easily prevented from light reflection on interfaces between a plurality of layers, whereby condensation efficiency for light incident upon the lenses can be improved.

In the aforementioned solid-state image sensor according to the first aspect, the lenses preferably have a radius of curvature of at least about 2 μm and not more than about 7 μm. According to this structure, the lenses can be so shaped as to exhibit excellent condensation efficiency. Thus, condensability of the solid-state image sensor can be improved.

The aforementioned solid-state image sensor according to the first aspect is preferably so constituted that the ratio of the distance between the substrate and the top portions of the lenses to the distance between the boundaries between adjacent pairs of lenses is at least about 0.7 and not more than about 1.3. According to this structure, the light condensed by the lenses can be easily focused on portions close to the centers of the photodetection parts having high photosensitivity. Thus, the photosensitivity of the solid-state image sensor can be easily improved.

The aforementioned solid-state image sensor according to the first aspect preferably further comprises a resin layer formed on the plurality of lenses. According to this structure, the resin layer can cover the surfaces of the lenses for inhibiting the surfaces from damage while inhibiting the boundaries between the lenses from contamination with foreign matter. The lenses consisting of an inorganic insulator generally have a larger refractive index than the resin layer having a refractive index of about 1.5, whereby the solid-state image sensor can refract light incident upon the lenses through the resin layer on the interface between the resin layer and the lenses also when the resin layer is provided on the lenses. Thus, the lenses can condense light incident upon the same through the resin layer on the photodetection part also when the resin layer is provided thereon. Further, the solid-state image sensor can vertically refract obliquely incident light on the upper surface of the resin layer, thereby verticalizing light incident upon the lenses through the resin layer. Thus, the solid-state image sensor can be inhibited from condensing light on regions deviating from portions close to the centers of the photodetection parts due to light obliquely incident upon the lenses, whereby the solid-state image sensor can condense obliquely incident light on the portions close to the centers of the photodetection parts having high photosensitivity. Consequently, the photosensitivity of the solid-state image sensor can be improved. Further, the resin layer is so formed on the lenses that a glass substrate or the like serving as a reinforcing plate can be bonded to the solid-state image sensor through the resin layer. Thus, the solid-state image sensor can be so improved in strength that the same can be inhibited from breakage when the lower surface of the substrate is subjected to polishing or the like. Also when the glass substrate is bonded to the solid-state image sensor through the resin layer, the solid-state image sensor can vertically refract obliquely incident light on the upper surface of the glass substrate. Thus, the solid-state image sensor can verticalize light incident upon the lenses also when the light obliquely enters the same. The glass substrate generally has a refractive index similar to that (about 1.5) of the resin layer, and hence the solid-state image sensor can inhibit the interface between the glass substrate and the resin layer from reflecting light also when the glass substrate is bonded to the solid-state image sensor through the resin layer.

In this case, the solid-state image sensor preferably further comprises an optical lens with an air space provided between the optical lens and the resin layer. The difference between the refractive indices of the optical lens and the air space is larger than the difference between those of the optical lens and the resin layer, and hence the solid-state image sensor can largely refract light on the lower surface of the optical lens according to the aforementioned structure, as compared with a solid-state image sensor having an optical lens and a resin layer integrated with each other. Thus, the solid-state image sensor can improve condensation efficiency through the optical lens as compared with the solid-state image sensor having the optical lens and the resin layer integrated with each other.

In the aforementioned structure including the resin layer, the solid-state image sensor preferably further comprises an optical lens so provided as to include no air space between the resin layer and the optical lens. According to this structure, the thickness of the solid-state image sensor can be reduced as compared with a solid-state image sensor having an optical lens and a resin layer including an air space therebetween.

A solid-state image sensor according to a second aspect of the present invention comprises a plurality of photodetection parts formed on a substrate and a plurality of lenses for condensing light on the photodetection parts. Each adjacent pair of lenses are so connected with each other as to include no substantially flat region on the boundary therebetween, and the plurality of lenses have a radius of curvature of at least about 2 μm and not more than about 7 μm.

In the solid-state image sensor according to the second aspect, as hereinabove described, each pair of adjacent lenses are so connected with each other as to include no substantially flat region on the boundary therebetween, so that no part of incident light is uncondensable on the boundary between the adjacent pair of lenses dissimilarly to lenses including a substantially flat region having no function of condensing light on photodetection parts on the boundary therebetween. Thus, condensation efficiency for the photodetection parts can be improved as compared with the lenses including a substantially flat region having no function of condensing light on the photodetection parts on the boundary therebetween, whereby the solid-state image sensor can attain high condensability. Further, the plurality of lenses, formed to have the radius of curvature of at least about 2 μm and not more than about 7 μm, can be so shaped as to exhibit excellent condensation efficiency. Thus, the condensability of the solid-state image sensor can be improved.

In the aforementioned solid-state image sensor according to the second aspect, the lenses preferably have a refractive index of at least about 1.6. According to this structure, the lenses can be easily provided with a large refractive index. Thus, the condensation efficiency through the lenses can be easily improved.

The aforementioned solid-state image sensor according to the second aspect preferably further comprises a resin layer formed on the plurality of lenses. According to this structure, the resin layer can cover the surfaces of the lenses for inhibiting the surfaces from damage while inhibiting the boundaries between the lenses from contamination with foreign matter. When the lenses are made of an inorganic insulator having a larger refractive index than the resin layer having a refractive index of about 1.5, the solid-state image sensor can refract light incident upon the lenses through the resin layer on the interface between the resin layer and the lenses also when the resin layer is provided on the lenses. Thus, the lenses can condense light incident upon the same through the resin layer on the photodetection part also when the resin layer is provided on the lenses. Further, the solid-state image sensor can vertically refract obliquely incident light on the upper surface of the resin layer, thereby verticalizing light incident upon the lenses through the resin layer. Thus, the solid-state image sensor can be inhibited from condensing light on regions deviating from portions close to the centers of the photodetection parts due to light obliquely incident upon the lenses, whereby the solid-state image sensor can condense obliquely incident light on the portions close to the centers of the photodetection parts having high photosensitivity. Consequently, the photosensitivity of the solid-state image sensor can be improved. Further, the resin layer is so formed on the lenses that a glass substrate or the like serving as a reinforcing plate can be bonded to the solid-state image sensor through the resin layer. Thus, the solid-state image sensor can be so improved in strength that the same can be inhibited from breakage when the lower surface of the substrate is subjected to polishing or the like. Also when the glass substrate is bonded to the solid-state image sensor through the resin layer, the solid-state image sensor can vertically refract obliquely incident light on the upper surface of the glass substrate. Thus, the solid-state image sensor can verticalize light incident upon the lenses also when the light obliquely enters the same. The glass substrate generally has a refractive index similar to that (about 1.5) of the resin layer, and hence the solid-state image sensor can inhibit the interface between the glass substrate and the resin layer from reflecting light also when the glass substrate is bonded to the solid-state image sensor through the resin layer.

In this case, the solid-state image sensor preferably further comprises an optical lens with an air space provided between the optical lens and the resin layer. The difference between the refractive indices of the optical lens and the air space is larger than the difference between those of the optical lens and the resin layer, and hence the solid-state image sensor can largely refract light on the lower surface of the optical lens according to the aforementioned structure, as compared with a solid-state image sensor having an optical lens and a resin layer integrated with each other. Thus, the solid-state image sensor can improve condensation efficiency through the optical lens as compared with the solid-state image sensor having the optical lens and the resin layer integrated with each other.

In the aforementioned structure including the resin layer, the solid-state image sensor preferably further comprises an optical lens so provided as to include no air space between the resin layer and the optical lens. According to this structure, the thickness of the solid-state image sensor can be reduced as compared with a solid-state image sensor having an optical lens and a resin layer including an air space therebetween.

A solid-state image sensor according to a third aspect of the present invention comprises a plurality of photodetection parts formed on a substrate and a plurality of lenses for condensing light on the photodetection parts. Each adjacent pair of lenses are so connected with each other as to include no substantially flat region on the boundary therebetween, and the solid-state image sensor is so constituted that the ratio of the distance between the substrate and the top portions of the lenses to the distance between the boundaries between adjacent pairs of lenses is at least about 0.7 and not more than about 1.3.

In the solid-state image sensor according to the third aspect, as hereinabove described, each adjacent pair of lenses are so connected with each other as to include no substantially flat region on the boundary therebetween so that no part of incident light is uncondensable on the boundary between the adjacent pair of lenses dissimilarly to lenses including a substantially flat region having no function of condensing light on photodetection parts on the boundary therebetween. Thus, condensation efficiency for the photodetection parts can be improved as compared with the lenses including a substantially flat region having no function of condensing light on the photodetection parts on the boundary therebetween, whereby the solid-state image sensor can attain high condensability. Further, the solid-state image sensor, so constituted that the ratio (aspect ratio) of the distance between the substrate and the top portions of the lenses to the distance between the boundaries between adjacent pairs of lenses is at least about 0.7 and not more than about 1.3, can easily focus the light condensed by the lenses on portions close to the centers of the photodetection parts having high photosensitivity. Thus, the photosensitivity of the solid-state image sensor can be easily improved.

In the aforementioned solid-state image sensor according to the third aspect, the lenses preferably have a refractive index of at least about 1.6. According to this structure, the lenses can be easily provided with a large refractive index. Thus, the condensation efficiency through the lenses can be easily improved.

In the aforementioned solid-state image sensor according to the third aspect, the lenses preferably have a radius of curvature of at least about 2 μm and not more than about 7 μm. According to this structure, the lenses can be so shaped as to exhibit excellent condensation efficiency. Thus, condensability of the solid-state image sensor can be improved.

The aforementioned solid-state image sensor according to the third aspect preferably further comprises a resin layer formed on the plurality of lenses. According to this structure, the resin layer can cover the surfaces of the lenses for inhibiting the surfaces from damage while inhibiting the boundaries between the lenses from contamination with foreign matter. When the lenses are made of an inorganic insulator having a larger refractive index than the resin layer having a refractive index of about 1.5, the solid-state image sensor can refract light incident upon the lenses through the resin layer on the interface between the resin layer and the lenses also when the resin layer is provided on the lenses. Thus, the lenses can condense light incident upon the same through the resin layer on the photodetection part also when the resin layer is provided thereon. Further, the solid-state image sensor can vertically refract obliquely incident light on the upper surface of the resin layer, thereby verticalizing light incident upon the lenses through the resin layer. Thus, the solid-state image sensor can be inhibited from condensing light on regions deviating from portions close to the centers of the photodetection parts due to light obliquely incident upon the lenses, whereby the solid-state image sensor can condense obliquely incident light on the portions close to the centers of the photodetection parts having high photosensitivity. Consequently, the photosensitivity of the solid-state image sensor can be improved. Further, the resin layer is so formed on the lenses that a glass substrate or the like serving as a reinforcing plate can be bonded to the solid-state image sensor through the resin layer. Thus, the solid-state image sensor can be so improved in strength that the same can be inhibited from breakage when the lower surface of the substrate is subjected to polishing or the like. Also when the glass substrate is bonded to the solid-state image sensor through the resin layer, the solid-state image sensor can vertically refract obliquely incident light on the upper surface of the glass substrate. Thus, the solid-state image sensor can verticalize light incident upon the lenses also when the light obliquely enters the same. The glass substrate generally has a refractive index similar to that (about 1.5) of the resin layer, and hence the solid-state image sensor can inhibit the interface between the glass substrate and the resin layer from reflecting light also when the glass substrate is bonded to the solid-state image sensor through the resin layer.

In this case, the solid-state image sensor preferably further comprises an optical lens with an air space provided between the optical lens and the resin layer. The difference between the refractive indices of the optical lens and the air space is larger than the difference between those of the optical lens and the resin layer, and hence the solid-state image sensor can largely refract light on the lower surface of the optical lens according to the aforementioned structure, as compared with a solid-state image sensor having an optical lens and a resin layer integrated with each other. Thus, the solid-state image sensor can improve condensation efficiency through the optical lens as compared with the solid-state image sensor having the optical lens and the resin layer integrated with each other.

In the aforementioned structure including the resin layer, the solid-state image sensor preferably further comprises an optical lens so provided as to include no air space between the resin layer and the optical lens. According to this structure, the thickness of the solid-state image sensor can be reduced as compared with a solid-state image sensor having an optical lens and a resin layer including an air space therebetween.

A solid-state image sensor according to a fourth aspect of the present invention comprises a plurality of photodetection parts formed on a substrate and a plurality of lenses for condensing light on the photodetection parts. Each adjacent pair of lenses are so connected with each other as to include no substantially flat region on the boundary therebetween, and the boundary between each adjacent pair of lenses has a thickness of at least about 10 nm.

In the solid-state image sensor according to the fourth aspect, as hereinabove described, each adjacent pair of lenses are so connected with each other as to include no substantially flat region on the boundary therebetween so that no part of incident light is uncondensable on the boundary between the adjacent pair of lenses dissimilarly to lenses including a substantially flat region having no function of condensing light on photodetection parts on the boundary therebetween. Thus, condensation efficiency for the photodetection parts can be improved as compared with the lenses including a substantially flat region having no function of condensing light on the photodetection parts on the boundary therebetween, whereby the solid-state image sensor can attain high condensability. Further, the boundary between the adjacent pair of lenses is formed to have the prescribed thickness of at least about 10 nm so that moisture can be inhibited from penetrating into the solid-state image sensor through the boundary between the adjacent pair of lenses. Thus, moisture resistance of the solid-state image sensor can be improved. Further, the boundary between the adjacent pair of lenses is so formed as to have the prescribed thickness of at least about 10 nm that no passivation film may be separately provided on the lenses for preventing penetration of moisture, whereby the thickness of the solid-state image sensor can be inhibited from increase.

In the aforementioned solid-state image sensor according to the fourth aspect, the lenses preferably have a refractive index of at least about 1.6. According to this structure, the lenses can be easily provided with a large refractive index. Thus, the condensation efficiency through the lenses can be easily improved.

In the aforementioned solid-state image sensor according to the fourth aspect, the lenses preferably have a radius of curvature of at least about 2 μm and not more than about 7 μm. According to this structure, the lenses can be so shaped as to exhibit excellent condensation efficiency. Thus, condensability of the solid-state image sensor can be improved.

The aforementioned solid-state image sensor according to the fourth aspect is preferably so constituted that the ratio of the distance between the substrate and the top portions of the lenses to the distance between the boundaries between adjacent pairs of lenses is at least about 0.7 and not more than about 1.3. According to this structure, the light condensed by the lenses can be easily focused on portions close to the centers of the photodetection parts having high photosensitivity. Thus, the photosensitivity of the solid-state image sensor can be easily improved.

The aforementioned solid-state image sensor according to the fourth aspect preferably further comprises a resin layer formed on the plurality of lenses. According to this structure, the resin layer can cover the surfaces of the lenses for inhibiting the surfaces from damage while inhibiting the boundaries between the lenses from contamination with foreign matter. When the lenses are made of an inorganic insulator having a larger refractive index than the resin layer having a refractive index of about 1.5, the solid-state image sensor can refract light incident upon the lenses through the resin layer on the interface between the resin layer and the lenses also when the resin layer is provided on the lenses. Thus, the lenses can condense light incident upon the same through the resin layer on the photodetection part also when the resin layer is provided thereon. Further, the solid-state image sensor can vertically refract obliquely incident light on the upper surface of the resin layer, thereby verticalizing light incident upon the lenses through the resin layer. Thus, the solid-state image sensor can be inhibited from condensing light on regions deviating from portions close to the centers of the photodetection parts due to light obliquely incident upon the lenses, whereby the solid-state image sensor can condense obliquely incident light on the portions close to the centers of the photodetection parts having high photosensitivity. Consequently, the photosensitivity of the solid-state image sensor can be improved. Further, the resin layer is so formed on the lenses that a glass substrate or the like serving as a reinforcing plate can be bonded to the solid-state image sensor through the resin layer. Thus, the solid-state image sensor can be so improved in strength that the same can be inhibited from breakage when the lower surface of the substrate is subjected to polishing or the like. Also when the glass substrate is bonded to the solid-state image sensor through the resin layer, the solid-state image sensor can vertically refract obliquely incident light on the upper surface of the glass substrate. Thus, the solid-state image sensor can verticalize light incident upon the lenses also when the light obliquely enters the same. The glass substrate generally has a refractive index similar to that (about 1.5) of the resin layer, and hence the solid-state image sensor can inhibit the interface between the glass substrate and the resin layer from reflecting light also when the glass substrate is bonded to the solid-state image sensor through the resin layer.

In this case, the solid-state image sensor preferably further comprises an optical lens with an air space provided between the optical lens and the resin layer. The difference between the refractive indices of the optical lens and the air space is larger than the difference between those of the optical lens and the resin layer, and hence the solid-state image sensor can largely refract light on the lower surface of the optical lens according to the aforementioned structure, as compared with a solid-state image sensor having an optical lens and a resin layer integrated with each other. Thus, the solid-state image sensor can improve condensation efficiency through the optical lens as compared with the solid-state image sensor having the optical lens and the resin layer integrated with each other.

In the aforementioned structure including the resin layer, the solid-state image sensor preferably further comprises an optical lens so provided as to include no air space between the resin layer and the optical lens. According to this structure, the thickness of the solid-state image sensor can be reduced as compared with a solid-state image sensor having an optical lens and a resin layer including an air space therebetween.

A solid-state image sensor according to a fifth aspect of the present invention comprises a plurality of photodetection parts formed on a substrate and a plurality of lenses for condensing light on the photodetection parts. Each adjacent pair of lenses are so connected with each other as to include no substantially flat region on the boundary therebetween, and the plurality of lenses are formed by a single layer.

In the solid-state image sensor according to the fifth aspect, as hereinabove described, each adjacent pair of lenses are so connected with each other as to include no substantially flat region on the boundary therebetween so that no part of incident light is uncondensable on the boundary between the adjacent pair of lenses dissimilarly to lenses including a substantially flat region having no function of condensing light on photodetection parts on the boundary therebetween. Thus, condensation efficiency for the photodetection parts can be improved as compared with the lenses including a substantially flat region having no function of condensing light on the photodetection parts on the boundary therebetween, whereby the solid-state image sensor can attain high condensability. Further, the plurality of lenses are formed by a single layer so that no interfaces are formed dissimilarly to lenses formed by a plurality of layers. Thus, the solid-state image sensor can be easily prevented from light reflection on interfaces between a plurality of layers, whereby efficiency for condensing light incident upon the lenses on the photodetection part can be improved.

The aforementioned solid-state image sensor according to the fifth aspect preferably further comprises a resin layer formed on the plurality of lenses. According to this structure, the resin layer can cover the surfaces of the lenses for inhibiting the surfaces from damage while inhibiting the boundaries between the lenses from contamination with foreign matter. When the lenses are made of an inorganic insulator having a larger refractive index than the resin layer having a refractive index of about 1.5, the solid-state image sensor can refract light incident upon the lenses through the resin layer on the interface between the resin layer and the lenses also when the resin layer is provided on the lenses. Thus, the lenses can condense light incident upon the same through the resin layer on the photodetection part also when the resin layer is provided thereon. Further, the solid-state image sensor can vertically refract obliquely incident light on the upper surface of the resin layer, thereby verticalizing light incident upon the lenses through the resin layer. Thus, the solid-state image sensor can be inhibited from condensing light on regions deviating from portions close to the centers of the photodetection parts due to light obliquely incident upon the lenses, whereby the solid-state image sensor can condense obliquely incident light on the portions close to the centers of the photodetection parts having high photosensitivity. Consequently, the photosensitivity of the solid-state image sensor can be improved. Further, the resin layer is so formed on the lenses that a glass substrate or the like serving as a reinforcing plate can be bonded to the solid-state image sensor through the resin layer. Thus, the solid-state image sensor can be so improved in strength that the same can be inhibited from breakage when the lower surface of the substrate is subjected to polishing or the like. Also when the glass substrate is bonded to the solid-state image sensor through the resin layer, the solid-state image sensor can vertically refract obliquely incident light on the upper surface of the glass substrate. Thus, the solid-state image sensor can verticalize light incident upon the lenses also when the light obliquely enters the same. The glass substrate generally has a refractive index similar to that (about 1.5) of the resin layer, and hence the solid-state image sensor can inhibit the interface between the glass substrate and the resin layer from reflecting light also when the glass substrate is bonded to the solid-state image sensor through the resin layer.

In this case, the solid-state image sensor preferably further comprises an optical lens with an air space provided between the optical lens and the resin layer. The difference between the refractive indices of the optical lens and the air space is larger than the difference between those of the optical lens and the resin layer, and hence the solid-state image sensor can largely refract light on the lower surface of the optical lens according to the aforementioned structure, as compared with a solid-state image sensor having an optical lens and a resin layer integrated with each other. Thus, the solid-state image sensor can improve condensation efficiency through the optical lens as compared with the solid-state image sensor having the optical lens and the resin layer integrated with each other.

In the aforementioned structure including the resin layer, the solid-state image sensor preferably further comprises an optical lens so provided as to include no air space between the resin layer and the optical lens. According to this structure, the thickness of the solid-state image sensor can be reduced as compared with a solid-state image sensor having an optical lens and a resin layer including an air space therebetween.

A method of manufacturing a solid-state image sensor according to a sixth aspect of the present invention comprises steps of forming a layer consisting of an inorganic insulator on a substrate formed with a photodetection part, forming a plurality of photoresist films on the layer consisting of an inorganic insulator to have a prescribed gap therebetween, performing heat treatment thereby upwardly convexing the plurality of photoresist films having the prescribed gap therebetween respectively and simultaneously etching the plurality of photoresist films having the prescribed gap therebetween and the layer consisting of an inorganic insulator with etching gas containing depositional gas thereby forming a plurality of upwardly convexed lenses without including a substantially flat region on the boundary therebetween.

In the method of manufacturing a solid-state image sensor according to the sixth aspect, as hereinabove described, the plurality of photoresist films having the prescribed gap therebetween and the layer consisting of an inorganic insulator are simultaneously etched with the etching gas containing depositional gas thereby forming the plurality of upwardly convexed lenses without including a substantially flat region on the boundary therebetween, whereby the lenses can be formed to include no substantially flat region having no function of condensing light on the photodetection part on the boundary therebetween after the etching also when the prescribed gap is provided between the photoresist films for preventing each adjacent pair of photoresist films from coming into contact with each other due to fluctuation resulting from heat treatment. Thus, no part of incident light is uncondensable on the boundary between each adjacent pair of lenses dissimilarly to lenses including a substantially flat region having no function of condensing light on photodetection parts on the boundary therebetween. Therefore, condensation efficiency for the photodetection part can be improved as compared with lenses including a substantially flat region having no function of condensing light on the photodetection part on the boundary therebetween, whereby a solid-state image sensor having high condensability can be easily formed.

In the aforementioned method of manufacturing a solid-state image sensor according to the sixth aspect, the depositional gas preferably contains CHF₃ gas. According to this structure, the lenses can be formed to include no substantially flat region having no function of condensing light on the photodetection part on the boundary between each adjacent pair of lenses after the etching also when the prescribed gap is provided between the photoresist films for preventing each adjacent pair of photoresist films from coming into contact with each other due to fluctuation resulting from heat treatment.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a side elevational view showing the overall structure of a solid-state image sensor according to a first embodiment of the present invention;

FIG. 2 is a sectional view of a CCD image sensor employed for the solid-state image sensor according to the first embodiment shown in FIG. 1;

FIG. 3 is a bottom plan view of the CCD image sensor employed for the solid-state image sensor according to the first embodiment shown in FIG. 1;

FIG. 4 is a top plan view of the CCD image sensor employed for the solid-state image sensor according to the first embodiment shown in FIG. 1;

FIG. 5 is a sectional view of a CCD part of the CCD image sensor employed for the solid-state image sensor according to the first embodiment shown in FIG. 1;

FIG. 6 is a sectional view for illustrating the structure of microlenses of the CCD image sensor employed for the solid-state image sensor according to the first embodiment shown in FIG. 1;

FIGS. 7 to 14 are sectional views for illustrating a process of manufacturing the CCD image sensor employed for the solid-state image sensor according to the first embodiment shown in FIG. 1;

FIG. 15 is a diagram for illustrating etching conditions for forming the microlenses of the CCD image sensor employed for the solid-state image sensor according to the first embodiment shown in FIG. 1;

FIGS. 16 to 18 are plan views schematically showing photomicrographs in cases of varying the etching conditions on the basis of FIG. 15 respectively;

FIG. 19 is a sectional view showing the structure of a solid-state image sensor according to a second embodiment of the present invention;

FIG. 20 is a circuit diagram of a CMOS image sensor employed for a solid-state image sensor according to a third embodiment of the present invention;

FIG. 21 is a sectional view showing the structure of the CMOS image sensor employed for the solid-state image sensor according to the third embodiment shown in FIG. 20; and

FIG. 22 is a sectional view showing the structure of an exemplary conventional solid-state image sensor.

### DESCRIPTION OF THE PREFERRED EMBODIMENTS

Embodiments of the present invention are now described with reference to the drawings.

(First Embodiment)

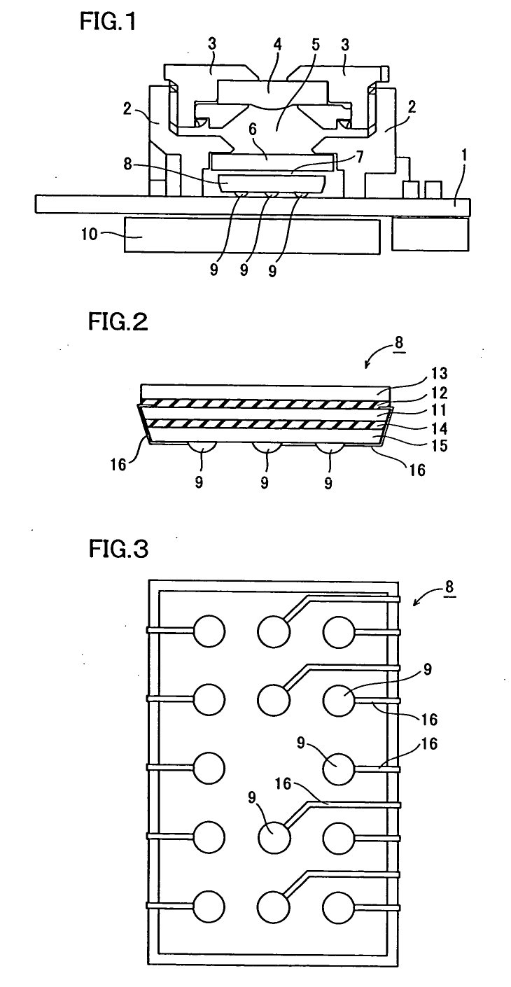

The structure of a solid-state image sensor employing a CCD (charge-coupled device) image sensor according to a first embodiment of the present invention is described with reference to FIGS. 1 to 6.

In the overall structure of the solid-state image sensor according to the first embodiment of the present invention, a ceramics holder 2 is provided on a printed board 1. A ceramics lens holder 3 is fixedly mounted on the upper portion of the holder 2. This lens holder 3 supports an optical lens 4 for condensing light reflected by an object.

According to the first embodiment, a CCD image sensor 8 is provided on the printed board 1. This CCD image sensor 8 is mounted on the upper surface of the printed board 1 with a plurality of solder balls 9 provided on the lower surface of the CCD image sensor 8. An air space 5, an infrared cut filter 6 and another air space 7 are interposed between the CCD image sensor 8 and the optical lens 4. The infrared cut filter 6, provided for cutting light in the infrared region from incident light, has a thickness of about 0.5 mm to about 1 mm. This infrared cut filter 6 is formed by evaporating a metal film on an SiO2 glass substrate.

A DSP (digital signal processor) 10 is provided on the lower surface of the printed board 1 for processing an image pickup signal supplied from the CCD image sensor 8.

As shown in FIG. 2, the CCD image sensor 8 comprises a CCD 11. A glass substrate 13 is integrally provided on the upper surface of the CCD 11 through a resin layer 12 consisting of acrylic resin. Another glass substrate 15 is integrally provided on the lower surface of the CCD 11 through another resin layer 14. The plurality of solder balls 9 are provided on the lower surface of the glass substrate 15 for mounting the CCD image sensor 8 on the printed board 1, as shown in FIGS. 2 and 3. Wires 16 are connected to the plurality of solder balls 9. The wires 16 are arranged along the lower surface and the side surfaces of the CCD image sensor 8 and connected to the CCD 11, as shown in FIG. 2.

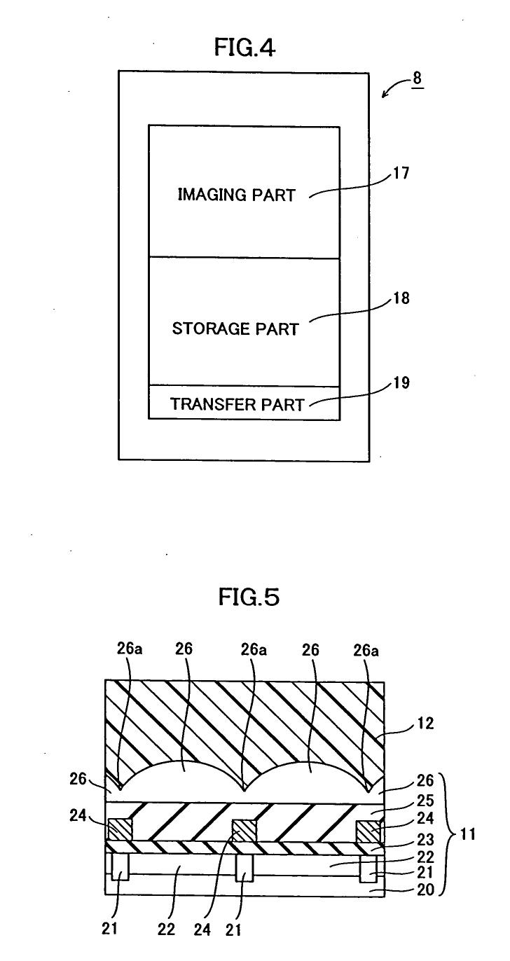

As shown in FIG. 4, the CCD image sensor 8 includes an imaging part 17 performing photoelectric conversion, a storage part 18 for temporarily storing charges photoelectrically converted by the imaging part 17, a transfer part 19 for transferring the charges stored in the storage part 18 to an output part (not shown) and the output part (not shown) for outputting the charges transferred from the transfer part 19. This CCD image sensor 8 has the so-called frame transfer structure.

In operation of the CCD image sensor 8, the imaging part 17 performs photoelectric conversion corresponding to an optical image applied thereto. Then, the imaging part 17 transfers (frame-shifts) the photoelectrically converted charges to the storage part 18 frame by frame. The transfer part 19 transfers a charge pattern formed in the storage part 18 to the output part (not shown) line by line. The output part (not shown) outputs the signal transferred thereto to a signal processing system such as the DSP 10 (see FIG. 1) as the image pickup signal of the CCD image sensor 8.

The sectional structure of the CCD 11 of the CCD image sensor 8 employed for the solid-state image sensor according to the first embodiment is described with reference to FIG. 5. The CCD 11 of the CCD image sensor 8 according to the first embodiment includes an Si substrate 20. This Si substrate 20 is an example of the “substrate” in the present invention. Pixel isolation parts 21 are formed on prescribed regions of the surface of the Si substrate 20 for isolating pixels from each other. Photodetection parts 22 having a photoelectric conversion function for converting incident light to signal charges are formed between the pixel isolation parts 21 of the Si substrate 20. The photodetection parts 22 are so formed that portions close to the centers of regions formed with the photodetection parts 22 (about ⅓ of the regions formed with the photodetection parts 22) have high photosensitivity with respect to the incident light. An interlayer dielectric film 23 having a thickness of about 0.24 (m is formed on the Si substrate 20 formed with the pixel isolation parts 21 and the photodetection parts 22. Screen films 24 having a thickness of about 1.0 (m and a width of about 0.2 (m to about 0.4 (m are formed on prescribed regions of the interlayer dielectric film 23. The screen films 24 are formed by stacking W (tungsten) films (not shown) and polysilicon films (not shown) with each other. The screen films 24 have a function of preventing the prescribed regions from incidence of light. Another interlayer dielectric film 25 consisting of a silicon oxide film having a thickness of about 1.5 (m is formed to cover the screen films 24 and the interlayer dielectric film 23. A plurality of microlenses 26 are formed on the interlayer dielectric film 25 in correspondence to the plurality of photodetection parts 22 respectively, for condensing light on the photodetection parts 22. The microlenses 26 are examples of the “lenses” in the present invention.

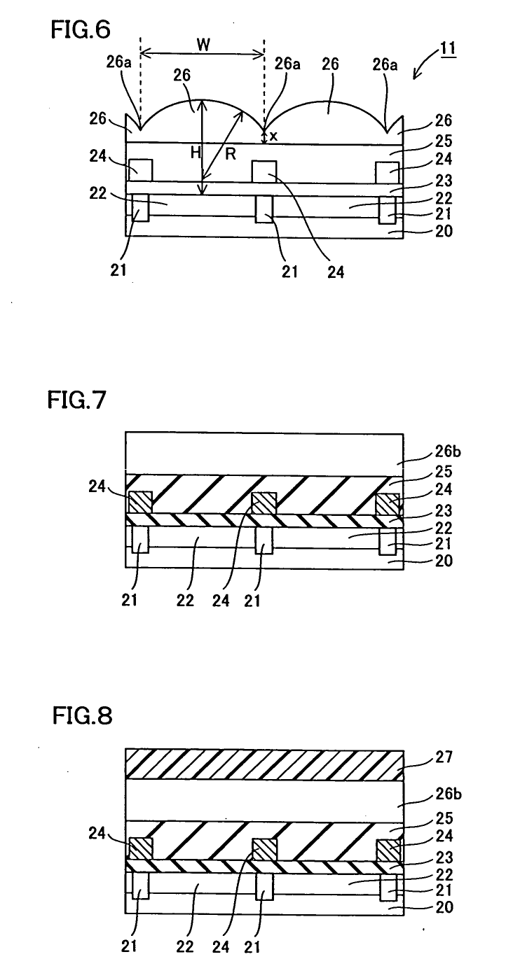

According to the first embodiment, the microlenses 26 are so formed that adjacent ones thereof include no substantially flat regions on boundaries 26a therebetween, as shown in FIG. 5. The microlenses 26 are formed by a single SiN film (silicon nitride film) having a refractive index of about 2.0. SiN is an example of the “inorganic insulator” in the present invention. Further, the microlenses 26 are so formed that the radius R of curvature thereof is at least 2 (m and not more than 7 (m, as shown in FIG. 6. The CCD 11 is so constituted that the ratio (aspect ratio: H/W) of the distance H between the Si substrate 20 and the top portions of the microlenses 26 to the distance W between the boundaries 26a between the adjacent microlenses 26 is at least 0.7 and not more than 1.3. The boundaries 26a between the adjacent microlenses 26a are so formed that the thickness x thereof is at least 10 nm.

According to the first embodiment, the resin layer 12 consisting of acrylic resin having the refractive index of about 1.5 is provided on the plurality of microlenses 26, as shown in FIG. 5. As hereinabove described, the glass substrate 13 (see FIG. 2), having the refractive index of about 1.5, serving as a reinforcing plate is integrally provided on the microlenses 26 through the resin layer 12.

According to the first embodiment, as hereinabove described, the adjacent microlenses 26 are so connected with each other as to include no substantially flat regions on the boundaries 26a therebetween, whereby no part of incident light is uncondensable on the boundaries 26a between the adjacent microlenses 26 dissimilarly to lenses including substantially flat regions having no function of condensing light on photodetection parts on the boundaries therebetween. Thus, condensation efficiency for the photodetection parts 22 can be improved as compared with the microlenses including substantially flat regions having no function of condensing light on the photodetection parts, whereby the solid-state image sensor can attain high condensability.

According to the first embodiment, further, the microlenses 26 formed by the SiN film having the refractive index of about 2.0 can be provided with a larger refractive index (about 2.0) as compared with microlenses formed by a resin layer (refractive index: about 1.5). Thus, condensation efficiency through the microlenses 26 can be improved. Further, the microlenses 26 are so formed by the single layer that no interfaces are formed dissimilarly to microlenses formed by a plurality of layers, whereby the solid-state image sensor is prevented from light reflection on interfaces between a plurality of layers.

The solid-state image sensor according to the first embodiment is so constituted that the ratio (aspect ratio: H/W) of the distance H between the Si substrate 20 and the top portions of the microlenses 26 to the distance W between the boundaries 26a between the adjacent microlenses 26 is at least 0.7 and not more than 1.3, whereby light condensed by the microlenses 26 can be easily focused on portions close to the centers of the photodetection parts 22 having high photosensitivity. Thus, the photosensitivity of the solid-state image sensor can be easily improved.

According to the first embodiment, the boundaries 26a between the adjacent microlenses 26 are formed to have the thickness of at least about 10 nm, whereby moisture can be effectively inhibited from penetrating into the solid-state image sensor through the boundaries 26a between the adjacent microlenses 26. thus, moisture resistance of the solid-state image sensor can be improved. Further, no passivation film may be separately provided on the microlenses 26 for preventing penetration of moisture due to the boundaries 26a between the adjacent microlenses 26 having the thickness of at least about 10 nm, whereby the thickness of the solid-state image sensor can be inhibited from increase.

According to the first embodiment, the resin layer 12 consisting of acrylic resin having the refractive index of about 1.5 is provided on the microlenses 26 to cover the surfaces thereof, thereby inhibiting the surfaces of the microlenses 26 from damage while inhibiting the boundaries 26a between the adjacent microlenses 26 from contamination with foreign matter. The refractive index (about 2.0) of the microlenses 26 consisting of the SiN film is larger than the refractive index (about 1.5) of the resin layer 12, whereby light transmitted through the resin layer 12 provided on the microlenses 26 and incident upon the microlenses 26 can be refracted on the interface between the resin layer 12 and the microlenses 26. Thus, the solid-state image sensor can condense the light incident upon the microlenses 26 through the resin layer 12 on the photodetection parts 22 also when the resin layer 12 is provided on the microlenses 26. Further, the solid-state image sensor can vertically refract obliquely incident light on the upper surface of the resin layer 12, thereby verticalizing light incident upon the microlenses 26 through the resin layer 12. Thus, the solid-state image sensor can be inhibited from condensing light on regions deviating from the portions close to the centers of the photodetection parts 22 due to light obliquely incident upon the microlenses 26, whereby the solid-state image sensor can condense obliquely incident light on the portions close to the centers of the photodetection parts 22 having high photosensitivity. Consequently, the photosensitivity of the solid-state image sensor can be improved.

According to the first embodiment, the glass substrate 13 having the refractive index of about 1.5 for serving as a reinforcing plate is integrally provided on the CCD 11 through the resin layer 12 for improving the strength of the CCD 11, whereby the CCD 11 can be inhibited from breakage when the lower surface of the Si substrate 20 is subjected to polishing or the like for adjusting the thickness of the Si substrate 20 or improving flatness thereof. Further, the solid-state image sensor capable of vertically refracting obliquely incident light on the upper surface of the glass substrate 13 can verticalize light incident upon the microlenses 26 also when the light obliquely enters the same. The glass substrate 13 has the refractive index similar to that (about 1.5) of the resin layer 12, and hence the solid-state image sensor can inhibit the interface between the glass substrate 13 and the resin layer 12 from reflecting light.

A process of manufacturing the CCD image sensor 8 employed for the solid-state image sensor according to the first embodiment is now described with reference to FIGS. 2, 5 and 7 to 18.

As shown in FIG. 7, the interlayer dielectric film 23 having the thickness of about 0.24 μm is formed on the Si substrate 20 formed with the pixel isolation parts 21 and the photodetection parts 22. The screen films 24, having the thickness of about 1.0 μm and the width of about 0.2 μm to about 0.4 μm, consisting of the W (tungsten) films and the polysilicon films are formed on the prescribed regions of the interlayer dielectric film 23. Thereafter the interlayer dielectric film 25 consisting of the silicon oxide film having the thickness of about 1.5 μm is formed to cover the screen films 24 and the interlayer dielectric film 23. Thereafter an SiN film 26b having a thickness of about 1.3 μm is formed on the interlayer dielectric film 25 by CVD (chemical vapor deposition). This SiN film 26b is an example of the “layer consisting of an inorganic insulator” in the present invention.

As shown in FIG. 8, a photoresist film 27 having a thickness of about 2 μm is applied onto the SiN film 26b.

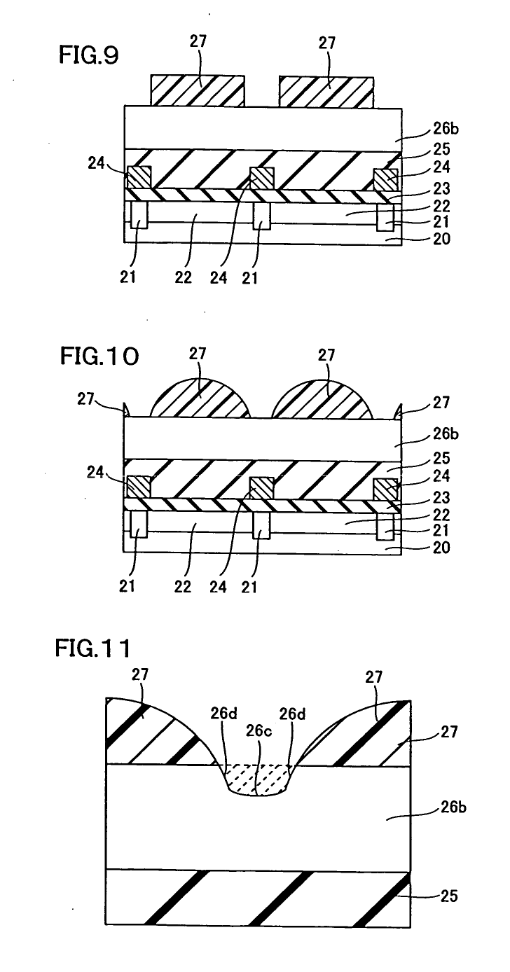

As shown in FIG. 9, the photoresist film 27 is worked into resist films 27 having a width of about 2.7 μm by lithography with a space of about 0.4 μm. The space of about 0.4 μm is so provided as to prevent the adjacent photoresist films 27 from coming into contact with each other due to fluidization resulting from later heat treatment. Thereafter ashing is so performed as to remove thin photoresist parts (not shown) remaining on portions of the SiN film 26b located between the adjacent photoresist films 27. This ashing is performed with 03 gas under a pressure of about 1 atm. and at a temperature of about 200° C. to about 400° C. for about 5 seconds to about 30 seconds. It is also possible to leave no photoresist parts on the portions of the SiN film 26b located between the adjacent photoresist films 26 by controlling treatment conditions for the lithography preceding the ashing. In this case, the ashing step can be omitted. Thereafter heat treatment is performed at a temperature of about 150° C. for about 30 minutes, thereby improving flowability of the photoresist films 27. Thus, the photoresist films 27 are upwardly convexed due to surface tension, as shown in FIG. 10. The plurality of photoresist films 27 having the upwardly convexed curved shape and the SiN film 26b are etched at the same time.

Thereafter etching is performed with etching gas containing depositional CHF₃ gas according to the first embodiment. More specifically, this etching is performed under conditions of a gas pressure of about 37.0 Pa to about 43.0 Pa, the etching gas consisting of the CHF₃ gas (about 5 ml to about 15 ml/s), CF₄ gas (about 60 ml/s to about 100 ml/s), Ar gas (about 600 ml/s to about 900 ml/s) and O₂ gas (about 25 ml/s to about 35 ml/s) and high-frequency power of about 120 W to about 200 W.

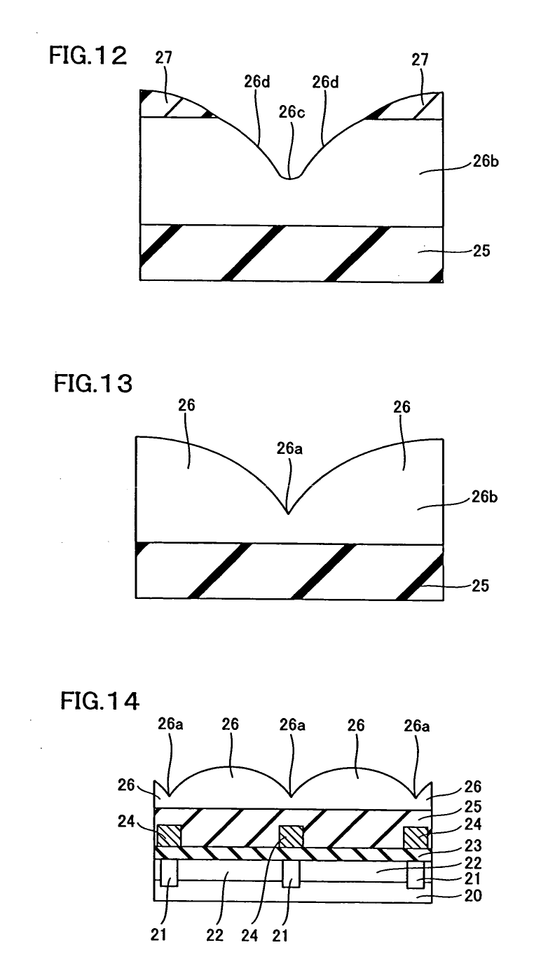

In this etching, the portion (shown by a broken line in FIG. 11) of the SiN film 26b located between each adjacent pair of photoresist films 27 is removed thereby forming a recess portion 26c, as shown in FIG. 11. The removed portion of the SiN film 26b is partially deposited on side surface 26d of the recess portion 26c due to the depositional CHF₃ gas added to the etching gas. Therefore, the depth of the recess portion 26c is increased and the width thereof is reduced along progress of the etching, as shown in FIG. 12. Consequently, the boundaries 26a between the adjacent microlenses 26 are formed to include no substantially flat portions, as shown in FIG. 13. Thus, the microlenses 26 are formed in an upwardly convexed curved shape and so connected with each other as to include no substantially flat portions on the boundaries 26a therebetween after the etching as shown in FIG. 14, also when the space of about 0.4 μm is provided between the adjacent photoresist films 27 (see FIG. 10).

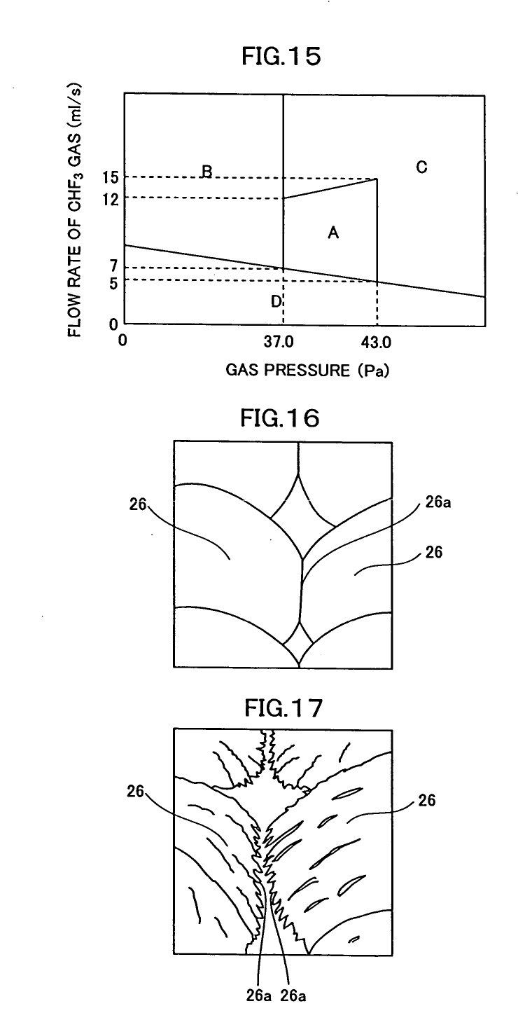

Results of actual observation of the shapes of the boundaries 26a between the adjacent microlenses 26 in cases of varying the gas pressure and the flow rate of CHF₃ gas in the etching steps shown in FIGS. 11 to 13 are described with reference to FIGS. 15 to 18. More specifically, it has been confirmed that the microlenses 26 were formed with smooth curved surfaces and the boundary 26a between each adjacent pair of microlenses 26 was smooth in plan view when the etching conditions were in the range A in FIG. 15 with a gas pressure of about 37.0 Pa to about 43.0 Pa and a CHF₃ gas flow rate of about 5 ml/s to about 15 ml/s, as shown in a schematic photomicrographic plan view of FIG. 16. When the surfaces of the microlenses 26 and the boundary 26a between each adjacent pair of microlenses 26 are formed as shown in FIG. 16, the solid-state image sensor can condense light incident upon the microlenses 26 on portions close to the centers of the photodetection parts 22 (see FIG. 14) having high photosensitivity. Therefore, the etching conditions are preferably set in the range A in FIG. 15 with the gas pressure of about 37.0 Pa to about 43.0 Pa and the CHF₃ gas flow rate of about 5 ml/s to about 15 ml/s. On the basis of this observation, the etching conditions in the range A in FIG. 15 are employed for the solid-state image sensor according to the first embodiment.

On the other hand, it has been confirmed that large numbers of small projecting and recess portions were formed on the surfaces of the microlenses 26 and the boundaries 26a between adjacent pairs of microlenses 26 when the etching conditions were in the range B in FIG. 15 with a gas pressure of less than about 37.0 Pa and a CHF₃ gas flow rate of at least about 7 ml/s, as shown in a schematic photomicrographic plan view of FIG. 17. When the microlenses 26 are formed as shown in FIG. 17, light is scattered on the surfaces of the microlenses 26 and the boundaries 26a between the adjacent microlenses 26, to reduce condensation efficiency of the microlenses 26. Large numbers of small projecting and recess portions are formed on the surfaces of the microlenses 26 and the boundaries 26a between adjacent microlenses 26 conceivably because the state of deposition with the CHF₃ gas is unstabilized due to the low gas pressure. Thus, it is conceivably unpreferable to set the etching conditions in the range B in FIG. 15.

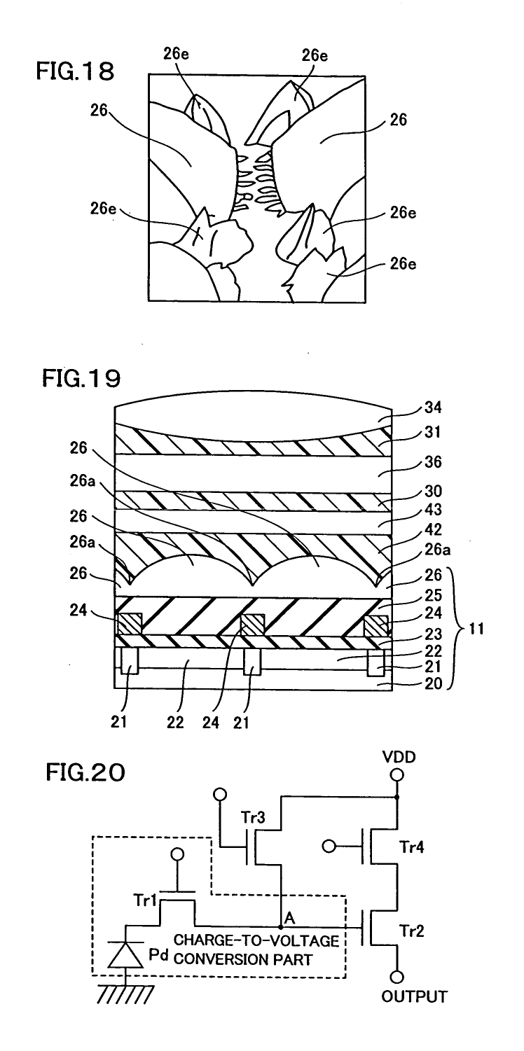

It has also been confirmed that the microlenses 26 were angularly formed while large convex portions 26e were formed around the microlenses 26 when the etching conditions were in the range C in FIG. 15 with a gas pressure of about 37.0 Pa to about 43-0.0 Pa and a CHF₃ gas flow rate of at least about 12 ml/s as well as a gas pressure of at least about 43.0 Pa and a CHF₃ gas flow rate of at least about 4 ml/s, as shown in a schematic photomicrographic plan view of FIG. 18. When the microlenses 26 are formed as shown in FIG. 18, light incident upon the microlenses 26 is not refracted in a constant direction and cannot be correctly condensed on the photodetection parts 22 (see FIG. 14). The microlenses 26 are formed as shown in FIG. 18 conceivably because of excess deposition with CHF₃ gas resulting from the large flow rate of CHF₃ gas and the high gas pressure. Thus, it is conceivably unpreferable to set the etching conditions in the range C in FIG. 15.

It has further been confirmed that gaps (flat portions: not shown) were formed on the boundaries 26a between the adjacent microlenses 26 when the etching conditions were in the range D in FIG. 15 with a CHF₃ gas flow rate of not more than about 9 ml/s. If such gaps (flat portions) having no function of condensing light on the photodetection parts 22 (see FIG. 14) are formed on the boundaries 26a between the adjacent microlenses 26, incident light is partially uncondensable onto the photodetection parts 22 on the boundaries 26a between the microlenses 26. Such gaps (flat portions) are formed on the boundaries 26a between the adjacent microlenses 26 conceivably because deposition is so insufficiently caused that the adjacent microlenses 26 are connected with each other to include the flat portions on the boundaries 26a due to the small CHF₃ gas flow rate. Thus, it is conceivably unpreferable to set the etching conditions in the range D in FIG. 15.

From the results of experiments shown in FIGS. 15 to 18, it has been proved that the etching conditions in the range A in FIG. 15 with the gas pressure of about 37.0 Pa to about 43.0 Pa and the CHF₃ gas flow rate of about 5 ml/s to about 15 ml/s are preferably employed in the etching steps shown in FIGS. 11 to 13.

After the structure shown in FIG. 14 is formed through the etching steps shown in FIGS. 11 to 13, the resin layer 12 of acrylic resin (refractive index: about 1.5) is formed on the microlenses 26, as shown in FIG. 5. Then, the glass substrate 13 is integrally bonded onto the resin layer 12 serving as an adhesive, as shown in FIG. 2. The glass substrate 15 is also integrally bonded to the lower surface of the Si substrate 20 through the resin layer 14 of acrylic resin. The plurality of solder balls 9 are set on the lower surface of the glass substrate 15, while the wires 16 are connected from the solder balls 9 to the CCD 11. Thus, the CCD image sensor 8 is formed to be employed for the solid-state image sensor according to the first embodiment.

(Second Embodiment)

In a solid-state image sensor according to a second embodiment of the present invention, a CCD, an infrared cut filter and an optical lens are integrated with each other dissimilarly to the aforementioned first embodiment.

In the solid-state image sensor according to the second embodiment, a glass substrate 43 is integrally bonded onto microlenses 26 of a CCD 11 through a resin layer 42 of acrylic resin serving as an adhesive, as shown in FIG. 19. An infrared cut filter 36 having a thickness of about 0.5 mm to about 1 mm is integrally bonded onto the glass substrate 43 through another resin layer 30 of acrylic resin serving as an adhesive, for cutting light of the infrared region from incident light. This infrared cut filter 36 is formed by evaporating a metal film on an SiO₂ glass substrate. An optical lens 34 is integrally bonded onto the infrared cut filter 36 through still another resin layer 31 of acrylic resin serving as an adhesive. The CCD 11 employed for the solid-state image sensor according to the second embodiment is similar in structure to the CCD 11 employed for the solid-state image sensor according to the aforementioned first embodiment.

According to the second embodiment, as hereinabove described, the glass substrate 43, the infrared cut filter 36 and the optical lens 34 are integrally bonded onto the microlenses 26 through the resin layers 42, 30 and 31 respectively with no air spaces provided therebetween, whereby the thickness of the solid-state image sensor can be reduced as compared with that according to the first embodiment.

The remaining effects of the second embodiment are similar to those of the aforementioned first embodiment.

(Third Embodiment)

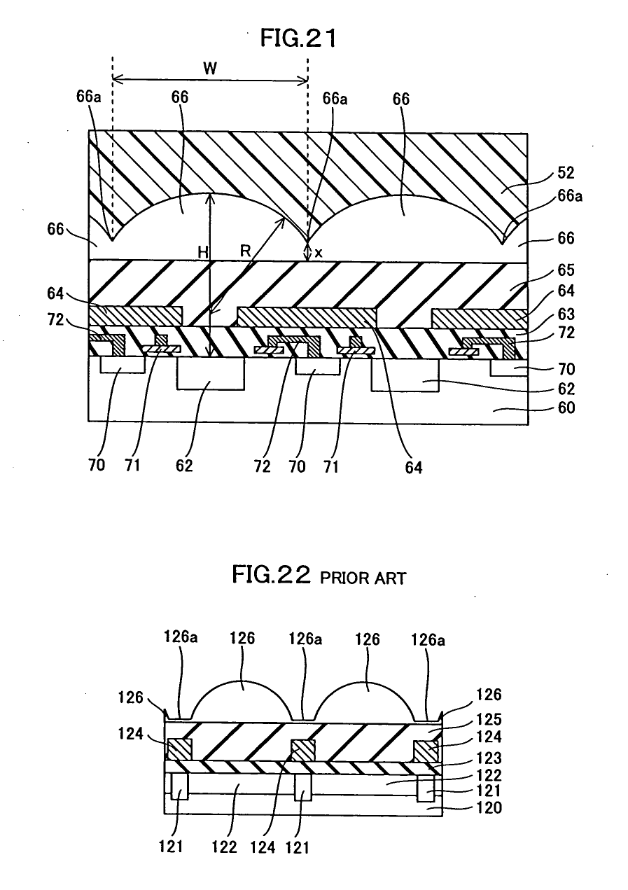

FIG. 21 shows the sectional structure of a CMOS image sensor employed for a solid-state image sensor according to a third embodiment of the present invention shown in FIG. 20. The sectional structure of the CMOS image sensor shown in FIG. 21 corresponds to that of a portion enclosed with broken lines in the circuit diagram of FIG. 20. The solid-state image sensor according to the third embodiment employs the CMOS image sensor, dissimilarly to the aforementioned first and second embodiments.

The overall structure of the CMOS image sensor employed for the solid-state image sensor according to the third embodiment is described with reference to FIG. 20. In the CMOS image sensor employed for the solid-state image sensor according to the third embodiment, a photodiode Pd (photodetection part) having a photoelectric conversion function is connected to the source of a transistor Tr1 having a read gate, as shown in FIG. 20. The drain of the transistor Tr1 is connected to the gate of another transistor Tr2 having a voltage-to-current conversion function and a current amplification function. A charge-to-voltage conversion part is provided between the drain of the transistor Tr1 and the gate of the transistor Tr2, for converting charges supplied from the photodiode Pd (photodetection part) to a voltage. The source of still another transistor Tr3 having a reset gate for resetting the charges supplied to the charge-to-voltage conversion part is connected to the charge-to-voltage conversion part. A positive potential VDD is supplied to the drain of the transistor Tr3.

The source of the transistor Tr2 is connected to an output line (not shown). The source of a further transistor Tr4 having a selector gate is connected to the drain of the transistor Tr2. A selection signal from an external scanning circuit (not shown) is supplied to the selector gate of the transistor Tr4. The positive potential VDD is supplied to the drain of the transistor Tr4.

In operation of the CMOS image sensor, a node A is held at the positive potential VDD in the initial state. Light incident upon the photodiode Pd (photodetection part) in this state is photoelectrically converted to form charges. When an ON signal is input in the read gate of the transistor Tr1, the charges formed in the photodiode Pd (photodetection part) are supplied to the charge-to-voltage conversion part (node A) through the transistor Tr1. The charges supplied to the node A are converted to a voltage responsive to the quantity of charges, whereby the transistor Tr2 is turned on in correspondence to the voltage responsive to the quantity of charges. When a selection signal for turning on the transistor Tr4 is input in the selector gate of the transistor Tr4 at this time, the transistor Tr4 is turned on so that a current corresponding to the charges formed in the photodiode Pd is output to the output line (not shown) from the positive potential VDD through the ON-state transistors Tr4 and Tr2.

When the selection signal for the transistor Tr4 is turned off in this state, the transistor Tr4 is also turned off to stop outputting the current to the output line (not shown). Thereafter an ON signal is input in the reset gate of the transistor Tr3 for turning on the transistor Tr3, thereby increasing the potential of the charge-to-voltage conversion part to the positive potential VDD, for resetting the charges supplied from the photodiode Pd to the charge-to-voltage conversion part.

The sectional structure of the CMOS image sensor according to the third embodiment is described with reference to FIG. 21. In the CMOS image sensor according to the third embodiment, a plurality of photodetection parts 62 having a photoelectric conversion function of converting incident light to signal charges are formed on prescribed regions of the surface of an Si substrate 60. Drain regions 70 of the same conductivity type as the photodetection parts 62 are formed on the surface of the Si substrate 60 at prescribed intervals from the photodetection parts 62. Read gates 71 are provided on portions of the surface of the Si substrate 60 located between the photodetection parts 62 and the drain regions 70. A charge-to-voltage conversion part 72 of Al or W (tungsten) is provided to be connected with the drain regions 70, for converting the charges supplied through the drain regions 70 to a voltage. This charge-to-voltage conversion part 72 is connected to the gate of a current amplification part (the transistor Tr2 in FIG. 20) having a voltage-to-current conversion function and a current amplification function.

An interlayer dielectric film 63 having a thickness of about 0.2 μm to about 0.3 μm is formed on the Si substrate 60 formed with the photodetection parts 62 and the drain regions 70, to cover the read gates 71 and the charge-to-voltage conversion part 72. Screen films 64 of W (tungsten) or the like having a thickness of about 0.5 μm and a width of about 2.7 μm are formed on prescribed regions of the interlayer dielectric film 63. The screen films 64 are provided on regions located above the read gates 71, the drain regions 70, the charge-to-voltage conversion part 72 and the current amplification part (the transistor Tr2 in FIG. 20). The screen films 64 have a function of preventing light from entering the charge-to-voltage conversion part 72 and the current amplification part (the transistor Tr2 in FIG. 20). Another interlayer dielectric film 65 of silicon oxide having a thickness of about 1.5 μm is formed to cover the screen films 64 and the interlayer dielectric film 63. A plurality of microlenses 66 are formed on the interlayer dielectric film 65 in correspondence to the plurality of photodetection parts 62 respectively, for condensing light on the photodetection parts 62.

According to the third embodiment, each adjacent pair of microlenses 66 are connected with each other to include no substantially flat region on the boundary 66a therebetween, as shown in FIG. 21. The microlenses 66 are formed by a single SiN film (silicon nitride film) having a refractive index of about 2.0. Further, the microlenses 66 are so formed that the radius R of curvature thereof is at least 2 μm and not more than 7 μm. The CMOS image sensor is so constituted that the ratio (aspect ratio (aspect ratio: H/W) of the distance H between the Si substrate 60 and the top portions of the microlenses 66 to the distance W between the boundaries 66a between the adjacent microlenses 66 is at least 0.7 and not more than 1.3. A resin layer 52 of acrylic resin having a refractive index of about 1.5 is provided on the microlenses 66. The remaining structure of the solid-state image sensor according to the third embodiment is similar to that of the solid-state image sensor according to the aforementioned first embodiment.

According to the third embodiment, as hereinabove described, the adjacent ones of the microlenses 66 are so connected with each other as to include no substantially flat regions on the boundaries 66a therebetween, whereby the CMOS image sensor can inhibit formation of incident light partially uncondensable on the boundaries 66a between the adjacent microlenses 66 dissimilarly to microlenses including substantially flat regions having no function of condensing light on photodetection parts on the boundaries therebetween. Thus, condensation efficiency for the photodetection parts 62 can be improved as compared with the microlenses including the substantially flat regions having no function of condensing light on the photodetection parts, whereby the solid-state image sensor can attain high condensability.

The remaining effects of the third embodiment are similar to those of the aforementioned first embodiment.

The CMOS image sensor according to the third embodiment has larger regions screened by the screen films 64 as compared with the CCD image sensor according to the first embodiment. In the CMOS image sensor according to the third embodiment, therefore, condensability of the solid-state image sensor can be further improved due to application of the microlenses 66 according to the present invention.

Although the present invention has been described and illustrated in detail, it is clearly understood that the same is by way of illustration and example only and is not to be taken by way of limitation, the spirit and scope of the present invention being limited only by the terms of the appended claims.

For example, while the microlenses 26 or 66 are applied to a CCD image sensor or a CMOS image sensor in each of the aforementioned embodiments, the present invention is not restricted to this but is also applicable to still another image sensor other than a CCD image sensor or a CMOS image sensor. Also when the present invention is applied to still another image sensor, effects similar to those of the aforementioned embodiments can be attained for improving condensation efficiency and the like.

While the present invention is applied to a frame transfer CCD image sensor in the aforementioned first embodiment, the present invention is not restricted to this but is also applicable to a CCD image sensor of another transfer system such as the so-called interline transfer system. Also when the present invention is applied to a CCD image sensor of another transfer system, effects similar to those of the aforementioned first embodiment can be attained for improving condensation efficiency and the like. A CCD image sensor of the interline transfer system has large screened regions due to employment of screen films having large areas, whereby condensability of a solid-state image sensor can be further effectively improved by applying the microlenses 26 according to the present invention.

While the lens holder 3 supporting the optical lens 4 is fixedly mounted on the holder 2 thereby fixing the optical lens 4 in the aforementioned first embodiment, the present invention is not restricted to this but the lens holder 3 supporting the optical lens 4 may alternatively be rendered vertically movable with respect to the holder 2 for rendering the optical lens 4 vertically movable. According to this structure, the distance between the optical lens 4 supported by the lens holder 3 and the CCD image sensor 8 set on the printed board 1 can be adjusted for adjusting the focus of the optical lens 4. The distance between the optical lens 4 and the CCD image sensor 8 may alternatively be rendered adjustable with means other than the lens holder 3 and the holder 2.

While the resin layer 12, 42 or 52 is provided on the microlenses 26 or 66 in each of the aforementioned embodiments, the present invention is not restricted to this but a color filter may be additionally provided on the resin layer 12, 42 or 52 provided on the microlenses 26 or 66. When the color filter is provided on the resin layer 12, 42 or 52 provided on the microlenses 26 or 66, a color CCD or CMOS image sensor can be prepared.

While the resin layer 12, 42 or 52 provided on the microlenses 26 or 66 and those for bonding the glass substrate 13 or 43 and the infrared cut filter 6 or 36, the infrared cut filter 6 and 36 and the optical lens 4 or 34 and the lower surface of the Si substrate 20 or 60 and the glass substrate 13 or 63 to each other respectively are prepared from acrylic resin in each of the aforementioned embodiments, the present invention is not restricted to this but another resin material other than the acrylic resin may alternatively be employed. For example, epoxy resin or the like may be employed.

While the inorganic insulator for forming the microlenses 26 or 66 is prepared from SiN having the refractive index of about 2.0 in each of the aforementioned embodiments, the present invention is not restricted to this but another inorganic insulator may alternatively be employed for forming the microlenses 26 or 66. For example, titanium oxide (refractive index: about 2.76), lead titanate (refractive index: about 2.7), potassium titanate (refractive index: about 2.68), titanium oxide anatase (refractive index: about 2.52), zircon oxide (refractive index: about 2.4), zinc sulfide (refractive index: about 2.37 to about 2.43), antimony oxide (refractive index: about 2.09 to about 2.29), zinc oxide (refractive index: about 2.01 to about 2.03) or white lead (refractive index: about 1.94 to about 2.09) is conceivable as the inorganic insulator.

While CHF₃ gas is employed as the depositional gas added to the etching gas in each of the aforementioned embodiments, the present invention is not restricted to this but another depositional gas other than the CHF₃ gas may alternatively be employed. For example, CH₂F₂ gas, C₄F₈ gas or C₂F₂ gas may alternatively be employed. Also when this depositional gas is employed, the adjacent pairs of microlenses 26 or 66 can be connected with each other to include no substantially flat regions having no function of condensing light on the photodetection parts 22 or 62 on the boundaries 26a or 66a therebetween after etching.

What is claimed is:

1. A solid-state image sensor comprising:
a plurality of photodetection parts formed on a substrate; and
a plurality of lenses consisting of an inorganic insulator for condensing light on said photodetection parts, wherein
each adjacent pair of said lenses are so connected with each other as to include no substantially flat region on the boundary therebetween, and
the boundary between each said adjacent pair of lenses has a prescribed thickness.

2. The solid-state image sensor according to claim 1, wherein
the boundary between each said adjacent pair of lenses has a thickness of at least about 10 nm.

3. The solid-state image sensor according to claim 1, wherein
said lenses consisting of an inorganic insulator have a refractive index of at least about 1.6.

4. The solid-state image sensor according to claim 1, wherein
said plurality of lenses are formed by a single layer.

5. The solid-state image sensor according to claim 1, wherein
said lenses have a radius of curvature of at least about 2 μm and not more than about 7 μm.

6. The solid-state image sensor according to claim 1, so constituted that the ratio of the distance between said substrate and the top portions of said lenses to the distance between the boundaries between adjacent pairs of said lenses is at least about 0.7 and not more than about 1.3.

7. The solid-state image sensor according to claim 1, further comprising a resin layer formed on said plurality of lenses.

8. The solid-state image sensor according to claim 7, further comprising an optical lens with an air space provided between said optical lens and said resin layer.

9. The solid-state image sensor according to claim 7, further comprising an optical lens so provided as to include no air space between said resin layer and said optical lens.

10. A solid-state image sensor comprising:
a plurality of photodetection parts formed on a substrate; and
a plurality of lenses for condensing light on said photodetection parts, wherein
each adjacent pair of said lenses are so connected with each other as to include no substantially flat region on the boundary therebetween, and
said plurality of lenses have a radius of curvature of at least about 2 μm and not more than about 7 μm.

11. The solid-state image sensor according to claim 10, wherein
said lenses have a refractive index of at least about 1.6.

12. The solid-state image sensor according to claim 10, further comprising a resin layer formed on said plurality of lenses.

13. The solid-state image sensor according to claim 12, further comprising an optical lens with an air space provided between said optical lens and said resin layer.

14. The solid-state image sensor according to claim 12, further comprising an optical lens so provided as to include no air space between said resin layer and said optical lens.

15. A solid-state image sensor comprising:
a plurality of photodetection parts formed on a substrate; and
a plurality of lenses for condensing light on said photodetection parts, wherein
each adjacent pair of said lenses are so connected with each other as to include no substantially flat region on the boundary therebetween,
said solid-state image sensor being so constituted that the ratio of the distance between said substrate and the top portions of said lenses to the distance between the boundaries between adjacent pairs of said lenses is at least about 0.7 and not more than about 1.3.

16. The solid-state image sensor according to claim 15, wherein
said lenses have a refractive index of at least about 1.6.

17. The solid-state image sensor according to claim 15, wherein
said lenses have a radius of curvature of at least about 2 μm and not more than about 7 μm.

18. The solid-state image sensor according to claim 15, further comprising a resin layer formed on said plurality of lenses.

19. The solid-state image sensor according to claim 18, further comprising an optical lens with an air space provided between said optical lens and said resin layer.

20. The solid-state image sensor according to claim 18, further comprising an optical lens so provided as to include no air space between said resin layer and said optical lens.

21. A solid-state image sensor comprising:
a plurality of photodetection parts formed on a substrate; and
a plurality of lenses for condensing light on said photodetection parts, wherein
each adjacent pair of said lenses are so connected with each other as to include no substantially flat region on the boundary therebetween, and
the boundary between each said adjacent pair of lenses has a thickness of at least about 10 nm.

22. The solid-state image sensor according to claim 21, wherein
said lenses have a refractive index of at least about 1.6.

23. The solid-state image sensor according to claim 21, wherein
said lenses have a radius of curvature of at least about 2 μm and not more than about 7 μm.

24. The solid-state image sensor according to claim 21, so constituted that the ratio of the distance between said substrate and the top portions of said lenses to the distance between the boundaries between adjacent pairs of said lenses is at least about 0.7 and not more than about 1.3.

25. The solid-state image sensor according to claim 21, further comprising a resin layer formed on said plurality of lenses.

26. The solid-state image sensor according to claim 25, further comprising an optical lens with an air space provided between said optical lens and said resin layer.

27. The solid-state image sensor according to claim 25, further comprising an optical lens so provided as to include no air space between said resin layer and said optical lens.

28. A solid-state image sensor comprising:
a plurality of photodetection parts formed on a substrate; and
a plurality of lenses for condensing light on said photodetection parts, wherein
each adjacent pair of said lenses are so connected with each other as to include no substantially flat region on the boundary therebetween, and
said plurality of lenses are formed by a single layer.

29. The solid-state image sensor according to claim 28, further comprising a resin layer formed on said plurality of lenses.

30. The solid-state image sensor according to claim 29, further comprising an optical lens with an air space provided between said optical lens and said resin layer.

31. The solid-state image sensor according to claim 29, further comprising an optical lens so provided as to include no air space between said resin layer and said optical lens.

32. A method of manufacturing a solid-state image sensor, comprising steps of:
forming a layer consisting of an inorganic insulator on a substrate formed with a photodetection part;
forming a plurality of photoresist films on said layer consisting of an inorganic insulator to have a prescribed gap therebetween;
performing heat treatment thereby upwardly convexing said plurality of photoresist films having said prescribed gap therebetween respectively; and
simultaneously etching said plurality of photoresist films having said prescribed gap therebetween and said layer consisting of an inorganic insulator with etching gas containing depositional gas thereby forming a plurality of upwardly convexed lenses without including a substantially flat region on the boundary therebetween.

33. The method of manufacturing a solid-state image sensor according to claim 32, wherein
said depositional gas contains CHF₃ gas.
